(19) United States
(12) Patent Application Publication
(10) Pub. No.: US 2024/0395885 A1
(43) Pub. Date: Nov. 28, 2024

(54) GRAPHENE OPTICAL DEVICE

(71) Applicant: TAI & SONS INDUSTRIAL CO., LTD., Tainan City (TW)

(72) Inventors: Ming-Hsiu TSAI, Tainan City (TW); Chih-Ting LIN, Tainan City (TW); Kuan-Chou LIN, Tainan City (TW)

(21) Appl. No.: 18/667,967

(22) Filed: May 17, 2024

(30) Foreign Application Priority Data
May 22, 2023 (TW) 112118940

(51) Int. Cl. H01L 29/423; H01L 27/12; H01L 29/16; H01L 29/417; H01L 29/76

(52) U.S. Cl. CPC H01L 29/4238; H01L 27/12; H01L 29/1606; H01L 29/41733; H01L 29/7606

(57) ABSTRACT

A graphene optical device includes a base, a plurality of graphene transistors, and an electrical connection structure. Each of the graphene transistors includes a graphene layer, a metal nanoparticle layer, an insulation layer, a polymer electrolyte layer, and an electrode unit. The electrode unit includes a source electrode, a drain electrode, a first gate electrode component which includes a plurality of first gate electrodes, and a second gate electrode component which includes a plurality of second gate electrodes. The insulation layer has an opening. The polymer electrolyte layer is disposed between the metal nanoparticle layer exposed from the opening and the first gate electrodes, and between the metal nanoparticle layer exposed from the opening and the second gate electrodes. The electrical connection includes a source electrode connecting unit, a drain electrode connecting unit, a first gate electrode connecting unit, and a second gate electrode connecting unit.

### CROSS-REFERENCE TO RELATED APPLICATION

This application claims priority to Taiwanese Invention Patent Application No. 112118940, filed on May 22, 2023, the entire disclosure of which is incorporated by reference herein.

### FIELD

The disclosure relates to an optical device, and more particularly to a graphene optical device.

### BACKGROUND

With the aging of population owing to a prolongation of life expectancy, and a decline in the birth rate, issues regarding medication treatment as well as healthcare have become hot topics nowadays. Phototherapy, due to advantages of non-invasion, high safety, and having few side effects, has gained more and more attention. Based on the practical requirement, a phototherapy treatment is usually conducted with provision of an irradiation light source having a certain wavelength. For instance, an infrared/far-infrared phototherapy is carried out by allowing a human body to be exposed under irradiation of an infrared/far-infrared light source. Since the human body itself is a far-infrared emitter, when a far-infrared ray irradiates the human body, it will generate a resonance effect with cells or water molecules in the human body, so as to activate the cells in the human body and stimulate the immune system thereof, thereby accelerating activations of various metabolic processes in the human body, and thus alleviating inflammation, swelling and pain.

Currently, a commonly used far-infrared phototherapy product may be a textile item having an infrared-emitting substance added therein. Under some circumstances, for conducting the phototherapy treatment, the human body may be exposed in a far-infrared environment, such as a large sauna room that provides far-infrared radiation. As for using the far-infrared phototherapy product, it is hard to control the intensity of radiation and to keep the radiation at a specific frequency range. In addition, the infrared-emitting substance is likely to fall off after the textile item is cleansed repeatedly for a long period of time, resulting in a decrease in radiation efficiency and quality. As for conducting the phototherapy treatment in the far-infrared environment, in addition to the space limitation, the impact of high temperature is a matter to be considered.

### SUMMARY

Therefore, an object of the disclosure is to provide a graphene optical device that can alleviate at least one of the drawbacks of the prior art.

According to the disclosure, the graphene optical device includes a base, a plurality of graphene transistors arranged on the base, and an electrical connection structure electrically connected to the graphene transistors.

Each of the graphene transistors includes a graphene layer formed on the base, a metal nanoparticle layer disposed on the graphene layer, an insulation layer, a polymer electrolyte layer, and an electrode unit. The electrode unit includes a source electrode and a drain electrode disposed at two opposite sides of the metal nanoparticle layer, and a first gate electrode component and a second gate electrode component disposed in a position between the source electrode and said drain electrode. The insulation layer covers the source electrode and the drain electrode, and has an opening from which the metal nanoparticle layer is exposed. The first gate electrode component and the second gate electrode component are disposed correspondingly in position to the opening. The first gate electrode component includes a plurality of first gate electrodes spaced apart at intervals, and the second gate electrode component includes a plurality of second gate electrodes spaced apart at intervals. The polymer electrolyte layer is disposed between the metal nanoparticle layer exposed from the opening and the first gate electrodes, and between the metal nanoparticle layer exposed from the opening and the second gate electrodes.

The electrical connection structure includes a source electrode connecting unit which is electrically connected to the source electrodes of the electrode units of the graphene transistors, a drain electrode connecting unit which is electrically connected to the drain electrodes of the electrode units, a first gate electrode connecting unit which is electrically connected to the first gate electrodes of the first gate electrode components of the electrode units, and a second gate electrode connecting unit which is electrically connected to the second gate electrodes of the second gate electrode components of the electrode units.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic top view illustrating an embodiment of a graphene optical device according to the disclosure.

FIG. 2 is cross-sectional view of FIG. 1 taken along line II-II.

FIG. 3 is a schematic top view illustrating film layer structures obtained in step (d) of a method for preparing the embodiment.

FIG. 4 is a cross-sectional view of FIG. 3 taken along line IV-IV.

FIG. 5 is a schematic top view illustrating a first semi-finished product obtained in step (e) of the method for preparing the embodiment.

FIG. 6 is a cross-sectional view of FIG. 5 taken along line VI-VI.

FIG. 7 is a schematic top view illustrating a second semi-finished product obtained in step (f) of the method for preparing the embodiment.

FIG. 8 is a cross-sectional view of FIG. 7 taken along line VIII-VIII.

FIG. 9 is a cross-sectional view illustrating a first structure obtained in step (g) of the method for preparing the embodiment.

FIG. 10 is a cross-sectional view illustrating a second structure obtained in step (h) of the method for preparing the embodiment.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

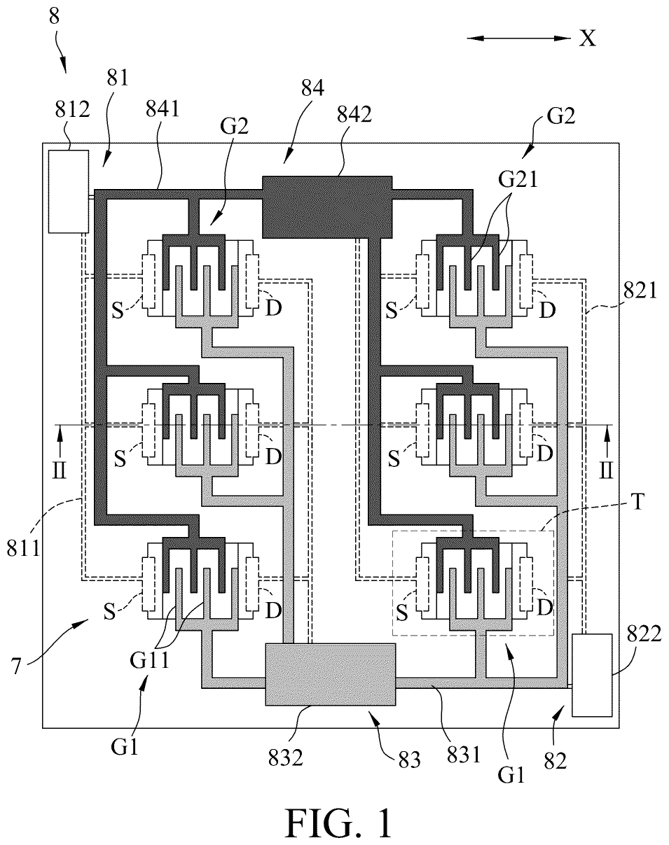

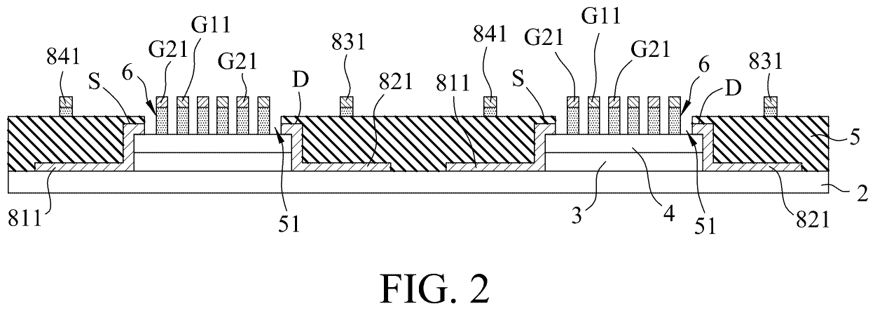

Referring to FIGS. 1 and 2, an embodiment of a graphene optical device according to the disclosure includes a base 2, a plurality of graphene transistors (T) arranged on the base 2, and an electrical connection structure 8.

The base 2 may be a silicon substrate, a glass substrate, or a polymer substrate made of a polymer material, such as polyethylene terephthalate (PET) or polyimide (PI). When the graphene optical device is applied to an optical pad, the base 2 may be the polymer substrate and has flexibility, so that the base 2 exhibits better adhesion to a surface which it is bonded to. In this embodiment, the base 2 is the polymer substrate made of PET and has flexibility, hence being applicable to the optical pad.

Each of the graphene transistors (T) includes a graphene layer 3 formed on the base 2, a metal nanoparticle layer 4 disposed on the graphene layer 3 and formed by a plurality of metal nanoparticles (not shown), an insulation layer 5, a polymer electrolyte layer 6, and an electrode unit 7.

The electrode unit 7 includes a source electrode (S) and a drain electrode (D) disposed at two opposite sides of the metal nanoparticle layer 4, and a first gate electrode component (G1) and a second gate electrode component (G2) disposed in a position between the source electrode (S) and the drain electrode (D). The insulation layer 5 covers the source electrode (S), the drain electrode (D), and an exposed surface of the base 2 (e.g., the surface not covered by the graphene layer 3, the source electrode (S) and the drain electrode (D)), and has an opening 51 which is located between the source electrode (S) and the drain electrode (D) and from which the metal nanoparticle layer 4 is exposed. That is to say, a surface of the metal nanoparticle layer 4 that is not covered by the source electrode (S) and the drain electrode (D) is exposed from the opening 51, and the first gate electrode component (G1) and the second gate component (G2) are disposed correspondingly in position to the opening 51. The first gate electrode component (G1) includes a plurality of first gate electrodes (G11) spaced apart at intervals, and the second gate electrode component (G2) includes a plurality of second gate electrodes (G21) spaced apart at intervals. The polymer electrolyte is disposed between the metal nanoparticle layer 4 exposed from the opening 51 and the first gate electrodes (G11), and between the metal nanoparticle layer 4 exposed from the opening 51 and the second gate electrodes (G21). Moreover, the first gate electrode component (G1) and the second gate electrode component (G2) are provided for separately controlling an applied voltage.

In some embodiments, the graphene transistors (T) are arranged in an array on the base 2. In still some embodiments, the graphene transistors (T) are arranged in rows and columns, and in each of the columns, the source electrodes (S) of the electrode units 7 of the graphene transistors (T) are located at a first side of the each of the columns, and the drain electrodes (D) of the electrode units 7 are located at a second side of the each of the columns opposite to the first side.

In this embodiment, in each of the graphene transistors (T), the graphene layer 3, from a top view, is a rectangle having a length extending along an X direction (hereinafter referred to as “length direction”), and the source electrode (S) and the drain electrode (D) of the electrode unit 7 are located at the two opposite sides of the metal nanoparticle layer 4 with respect to the length direction. In addition, the first gate electrodes (G11) and the second gate electrodes (G21) are located correspondingly at two opposite sides of the opening 51 with respect to a width direction perpendicular to the length direction, extend toward each other, and are alternately arranged in an interdigitated manner.

In certain embodiments, in each of the graphene transistors (T), each of the first gate electrodes (G11) has a first width ranging from 100 nm to 2 μm, each of the second gate electrodes (G21) has a second width ranging from 100 nm to 2 μm, and one of the first gate electrodes (G11) is spaced apart from an adjacent one of the second gate electrodes (G21) by a distance ranging from 100 nm to 2 μm. In some embodiments, in each of the graphene transistors (T), the first gate electrodes (G11) and the second gate electrodes (G21) are arranged at regular intervals ranging from 100 nm to 2 μm; in still some embodiments, each of the regular intervals has a third width, each of the first width, the second width and the third width ranges from 100 nm to 2 μm, and the first width, the second width and the third width are equal.

In more detail, the metal nanoparticle layer 4 in each of the graphene transistors (T) is formed on a surface of the graphene layer 3, and includes the metal nanoparticles (not shown). The metal nanoparticles may be made of a precious metal, e.g., gold (Au), platinum (Pt), silver (Ag), combinations thereof, and so forth.

The insulation layer 5 may be made of an insulation material, e.g., polymer, inorganic oxide, and nitride.

Moreover, the polymer electrolyte layer 6 may include a polymer electrolyte and a photoresist, and has developing ability. In certain embodiments, the polymer electrolyte is a solid electrolyte material, e.g., a mixture of polyethylene oxide (PEO) and lithium bis(trifluoromethanesulfonyl)imide (Li[(CF₃SO₂)₂N]; LiTFSI), and a mixture of carboxylated cellulose microfibrils (CCMFs) and carboxylated cellulose nanofibrils (CCNFs). Additionally, the photoresist may be a positive photoresist or a negative photoresist. In an exemplary embodiment, the photoresist is SU-8 negative photoresist, and the solid electrolyte material that serves as the polymer electrolyte is the mixture of PEO and LiTFSI.

In order to maintain the property and developing ability of the polymer electrolyte layer 6, in some embodiments, a weight ratio of the polymer electrolyte to the photoresist ranges from 1:2 to 2:1, and in still some embodiments, the weight ratio thereof ranges from 7:10 to 1:1.

In this embodiment, the metal nanoparticles are silver (Ag) nanoparticles which have a particle size ranging from 70 nm to 150 nm and are capable of providing a reduction in loss of infrared radiation. The insulation layer 5 is formed by using an SU-8 photoresist. The opening 51, from the top view, is in a rectangular shape having a length of 50 μm and a width of 25 μm (size: 50 μm×25 μm). The polymer electrolyte layer 6 includes the mixture of PEO and LiTFSI (serving as the polymer electrolyte) and SU-8 negative photoresist (serving as the photoresist), and a weight ratio between the mixture of PEO and LiTFSI and the SU-8 negative photoresist is 7:10. In certain embodiments, each of the source electrode (S), the drain electrode (D), the first gate electrode component (G1) and the second gate electrode component (G2) has a double-layered structure having a gold (Au) layer with a thickness of 80 nm and a titanium (Ti) layer with a thickness of 5 nm (i.e., Au (80 nm)/Ti (5 nm)). However, the foregoing example does not intend to be a limitation in an actual implementation.

The electrical connection structure 8 is electrically connected to the graphene transistors (T), and more specifically, to the electrode units 7 of the graphene transistors (T). In addition, the electrical connection structure 8 includes a source electrode connecting unit 81 which is electrically connected to the source electrodes (S) of the electrode units 7 of the graphene transistors (T), a drain electrode connecting unit 82 which is electrically connected to the drain electrodes (D) of the electrode units 7, a first gate electrode connecting unit 83 which is electrically connected to the first gate electrodes (G11) of the first gate electrode components (G1) of the electrode units 7, and a second gate electrode connecting unit 84 which is electrically connected to the second gate electrodes (G21) of the second gate electrode components (G2) of the electrode units 7. Furthermore, the first gate electrode connecting unit 83 and the second gate electrode connecting unit 84 are disposed on the insulation layer 5 and the polymer electrolyte layer 6, and electrically isolated from the source electrode connecting unit 81 and the drain electrode connecting unit 82 by the insulation layer 5.

Specifically, the source electrode connecting unit 81 includes a plurality of source electrode connection wires 811 which connect the source electrodes (S) in parallel, and a source electrode connection pad 812 which is electrically connected to the source electrode connection wires 811. The drain electrode connecting unit 82 includes a plurality of drain electrode connection wires 821 which connect the drain electrodes (D) in parallel, and a drain electrode connection pad 822 which is electrically connected to the drain electrode connection wires 821. The first gate electrode connecting unit 83 includes a plurality of first gate electrode connection wires 831 which connect the first gate electrodes (G11) in parallel, and a first gate electrode connection pad 832 which is electrically connected to the first gate electrode connection wires 831. The second gate electrode connecting unit 84 includes a plurality of second gate electrode connection wires 841 which connect the second gate electrodes (G21) in parallel, and a second gate electrode connection pad 842 which is electrically connected to the second gate electrode connection wires 841.

In this embodiment, each of the source electrode connection wires 811, the drain electrode connection wires 821, the first gate electrode connection wires 831, the second gate electrode connection wires 841, the source electrode connection pad 812, the drain electrode connection pad 822, the first gate electrode connection pad 832, and the second gate electrode connection pad 842 has a double-layered structure containing a gold (Au) layer having a thickness of 80 nm and a titanium (Ti) layer having a thickness of 5 nm (i.e., Au (80 nm)/Ti (5 nm)). Each of the source electrode connection wires 811 and the drain electrode connection wires 821 has a wire width of approximately 10 μm, and each of the first gate electrode connection wires 831 and the second gate electrode connection wires 841 has a wire width of approximately 20 μm. Additionally, the polymer electrolyte layer 6 may also exist at sites between the insulation layer 5 and the first gate electrode connection wires 831, and between the insulation layer 5 and the second gate electrode connection wires 841. However, in an actual circumstance, the first gate electrode connection wires 831 and the second gate electrode connection wires 841 may be formed directly on the insulation layer 5, and the wire widths of the abovementioned wires 811, 821, 831, 841 may vary depending on a desired number of the graphene transistors (T) as well as actual needs, and hence are not limited thereto.

It is commonly known that a transistor usually includes a gate dielectric material therein, such as silicon dioxide (SiO₂), hafnium dioxide (HfO₂), poly(methyl methacrylate) (PMMA), polystyrene (PS), polyimide and so on. Nevertheless, when the transistor including the gate dielectric material has a relatively large surface area, such transistor requires a higher operating voltage (it takes approximately tens of volts to produce an effective change in electric dipole in the gate dielectric material, where an obvious electrical doping effect can be obtained). Moreover, it is well known that a polarization status in the gate dielectric material is changed by applying an external electrical field, so if there are defects inside a gate dielectric layer made of the gate dielectric material, a charge channel can be easily formed, resulting in a significant reduction in doping effect. Besides, it is very hard to control a defect density of the gate dielectric material. In the embodiment of the graphene optical device according to the disclosure, the polymer electrolyte contained in the polymer electrolyte layer 6 is used to replace the gate dielectric material conventionally used, so the foregoing issues regarding defects in the gate dielectric material can be avoided. In addition, by simply applying an external bias voltage to the polymer electrolyte, doped ions therein can be transmitted, through pores of an amorphous substance of the polymer electrolyte, to an interface. As a result, for achieving a doping effect in a gate electrode, a gate bias voltage required is merely about +1 V, thus effectively reducing the operating voltage of the graphene optical device. Since the polymer electrode layer 6 also includes the photoresist and has the developing ability, it can be formed using photolithography, which effectively simplifies the manufacturing process thereof. Furthermore, in the embodiment of the graphene optical device according to the disclosure, because the graphene transistors (T) on the base 2 are in an array arrangement (e.g., an array of graphene field-effect transistors (GFETs)), the disadvantage of an excessively large surface area happened to the foregoing transistor can be solved by reducing a surface area of each of the graphene transistors (T), and simultaneously, a total luminous intensity of the graphene optical device can be elevated by increasing the number of the graphene transistors (T) per unit surface area of the graphene optical device.

Because the graphene optical device emits light having a wavelength ranging from 750 nm to 100 μm, it can be used as an infrared light/far-infrared light-emitting patch (i.e., serving as an optical patch). When the graphene optical device according to the disclosure is used to serve as the optical patch, it may be attached to a target portion of a human body with the base 2 thereof facing toward the target portion, and by controlling a voltage to be applied through the first gate electrode components (G1) and the second gate electrode components (G2)), the graphene transistors (T) can emit a desired wavelength and intensity of light.

Since the base 2 of the graphene optical device according to the disclosure may be flexible, the graphene optical device may be properly fitted to the target portion of the human body, thus being suitable for topical use. In addition, by using the first gate electrode connecting unit 83 and the second gate electrode connecting unit 84 to respectively control a voltage applied to the first gate electrode components (G1) and a voltage applied to the second gate electrode components (G2), the polymer electrolyte in the polymer electrolyte layer 6 can be polarized, so that an electron-hole recombination is generated at an interface between the graphene layer 3 and the metal nanoparticle layer 4, thereby emitting light. Moreover, the light thus emitted can be reflected by the metal nanoparticles of the metal nanoparticle layer 4, which in turn causes the light to radiate back to graphene of the graphene layer 3, thereby generating graphene plasmons and hence obtaining a gain effect. Through voltage regulation, the graphene in the graphene optical device emits light with a predetermined optical band, so as to avoid interference from light of other optical bands. Because silver is capable of providing a reduction in loss of far-infrared radiation, when the metal nanoparticles used in the disclosure are silver nanoparticles, the graphene optical device possesses better far-infrared light luminescence effect.

A method for preparing this embodiment of the graphene optical device is described below.

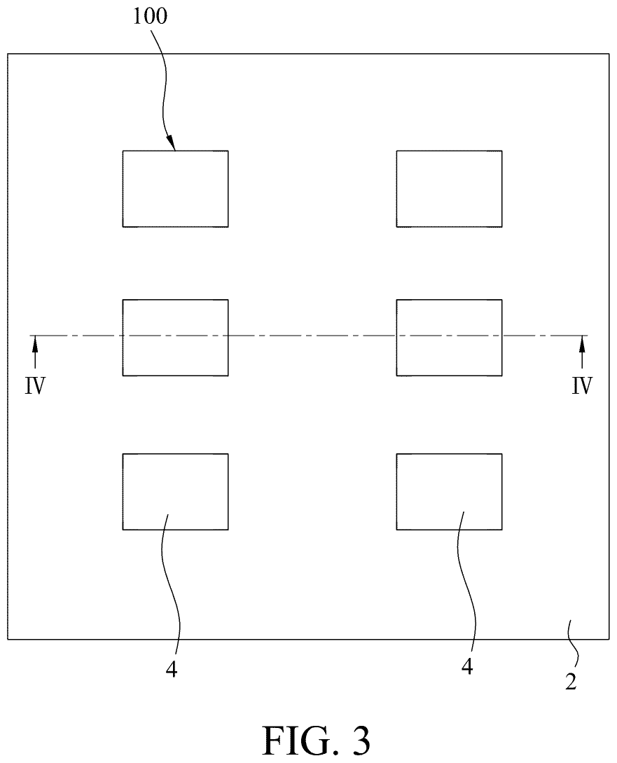

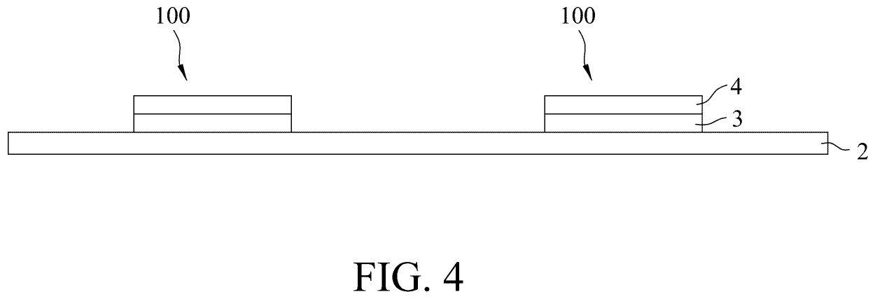

Referring to FIGS. 3 and 4, initially, in step (a), the base 2, e.g., a PET substrate, is provided.

Next, in step (b), the graphene layer 3 is formed on a surface of the base 2.

To be specific, the graphene layer 3 is formed by steps as follows. First, a carbon source layer, which is made of a mixture of a polycyclic aromatic hydrocarbon (PAH) and 1-octylphosphonic acid (OPA) present in a weight ratio of 91.9 to 9.1, is coated on the surface of the base 2, and subsequently, a copper layer is formed on the carbon source layer using sputtering or electron beam evaporation. Thereafter, the carbon source layer and the copper layer are subjected to a vacuum heating treatment in a high-temperature furnace tube at 400° C. to 600° C., so as to convert the carbon source layer into the graphene layer 3. Finally, the copper layer is removed by electrolytic separation or etching. It should be noted that the foregoing steps for forming the graphene layer 3 is merely for illustration, and the disclosure is not intended to be limited thereto.

After that, in step (c), the metal nanoparticle layer 4 including the metal nanoparticles is formed on the surface of the graphene layer 3 by spin coating.

Subsequently, in step (d), a patterned photoresist layer is formed on a portion of the metal nanoparticle layer 4 by photolithography, followed by removing another portion of the metal nanoparticle layer 4 that is not covered by the patterned photoresist layer and a portion of the graphene layer 3 beneath the another portion of the metal nanoparticle layer 4, and then removing the pattern photoresist layer, thereby forming plural layered structures 100, as shown in FIGS. 3 and 4, which are arranged in an array and spaced apart from one another on the surface of the base 2. Additionally, FIG. 3 is a schematic top view of the layered structures 100, and FIG. 4 is a cross-sectional view of FIG. 3 taken along line IV-IV. In this embodiment, each of the layered structures 100, from the top view, is in a rectangular shape having a length of 50 μm and a width of 25 μm (size: 50 μm×25 μm), and a distance between any two adjacent ones of the layered structures 100 is 50 μm.

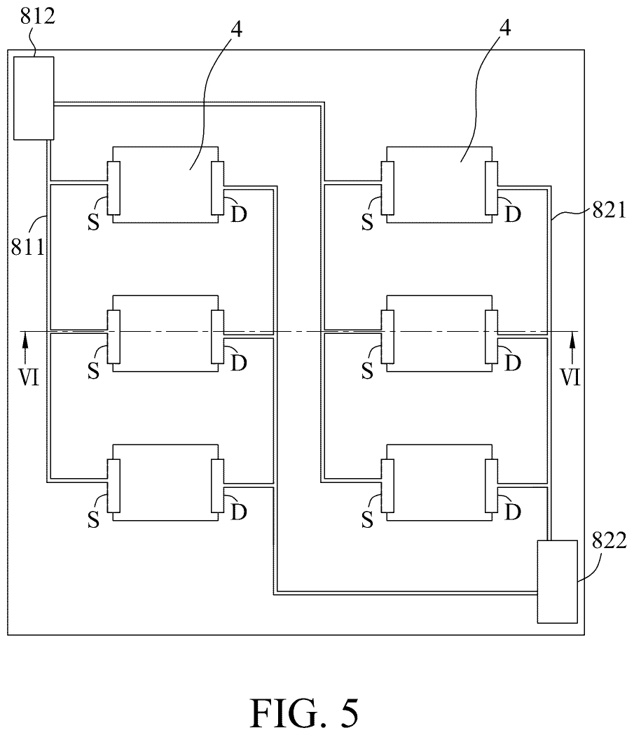

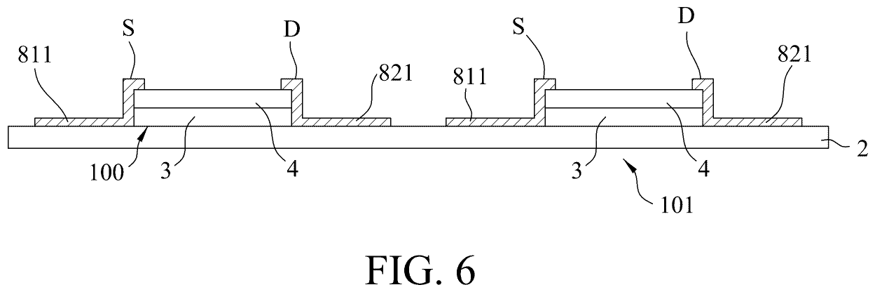

Thereafter, in step (e), a photoresist material such as an SU-8 photoresist is used to form a first photoresist layer on the surface of the base 2 as well as on surfaces of the layered structures 100, followed by, using photolithography to remove portions of the photoresist material (i.e., the first photoresist layer) located at locations where the source electrodes (S), the drain electrodes (D), the source electrode connection wires 811, the drain electrode connection wires 821, the source electrode connection pad 812, and the drain electrode connection pad 822 are to be formed subsequently. Next, gold (having a thickness of 80 nm) and titanium (having a thickness of 5 nm) are deposited sequentially at sites where the portions of the photoresist material are removed, followed by removing the remaining of the photoresist material (i.e., the first photoresist layer), so that the source electrodes (S), the drain electrodes (D), the source electrode connection wires 811, the drain electrode connection wires 821, the source electrode connection pad 812, and the drain electrode connection pad 822 are formed, thereby obtaining a first semi-finished product 101 as shown in FIGS. 5 and 6. FIG. 5 is a schematic top view of the first semi-finished product 101, and FIG. 6 is a cross-sectional view of FIG. 5 taken along line VI-VI.

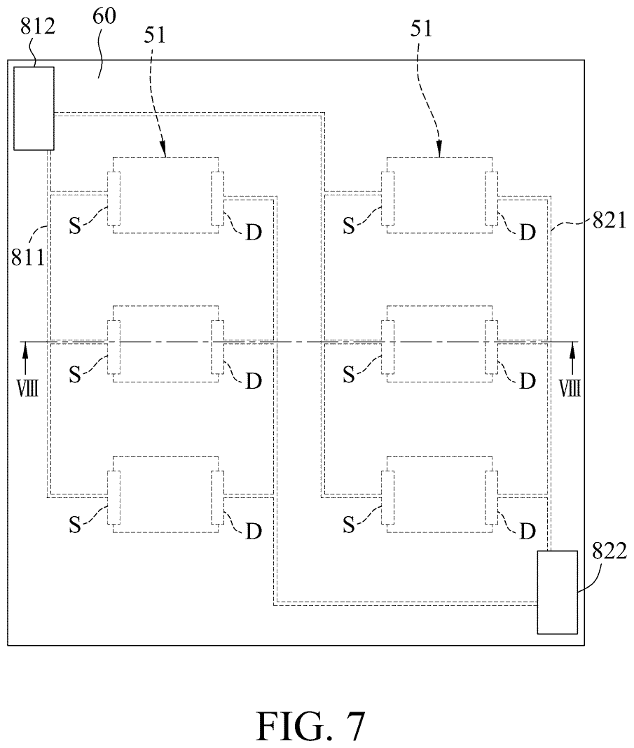

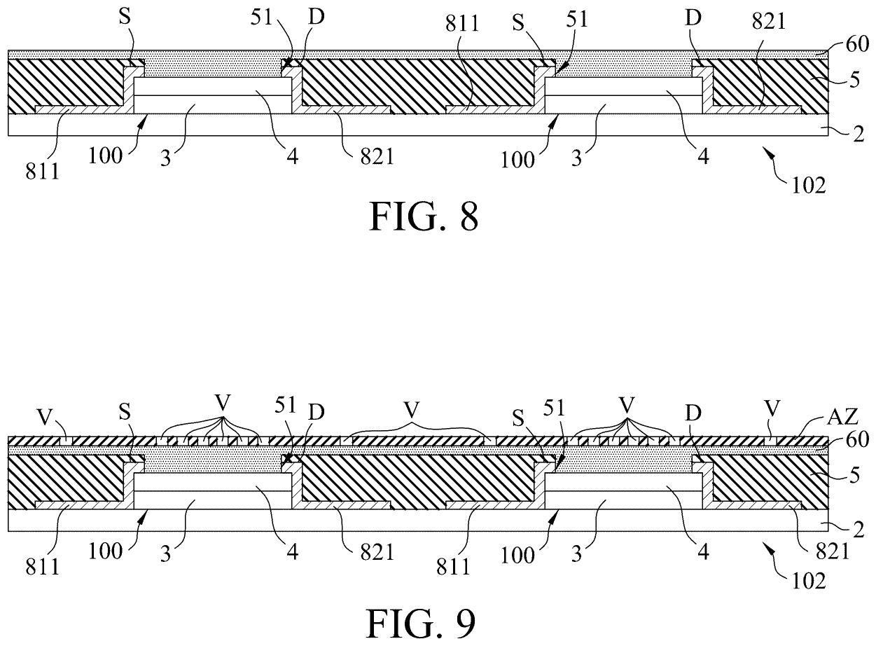

Next, referring to FIGS. 7 and 8, in step (f), another photoresist material such as an SU-8 photoresist is used to cover a surface of the first semi-finished product 101, so as to form the insulation layer 5 thereon, followed by, using photolithography to remove portions of the insulation layer 5 that are in position on surfaces of the source electrode connection pad 812, the drain electrode connection pad 822, and the layered structures 100, so as to expose the source electrode connection pad 812 and the drain electrode connection pad 822, and simultaneously, to form the openings 51 that expose the surfaces of the layered structures 100 (i.e., the surface of the metal nanoparticle layer 4). Subsequently, by spin coating, a solid electrolyte mixing material is coated on a surface of the insulation layer 5 and the surface of the metal nanoparticle layer 4 that is exposed from the openings 51, so as to form a polymer electrolyte film 60, thereby obtaining a second semi-finished product 102 as shown in FIG. 7 and FIG. 8. FIG. 7 is a schematic top view of the second semi-finished product 102, and FIG. 8 is a cross-sectional view of FIG. 7 taken along line VIII-VIII. The solid electrolyte mixing material includes the polymer electrolyte and the photoresist as mentioned above.

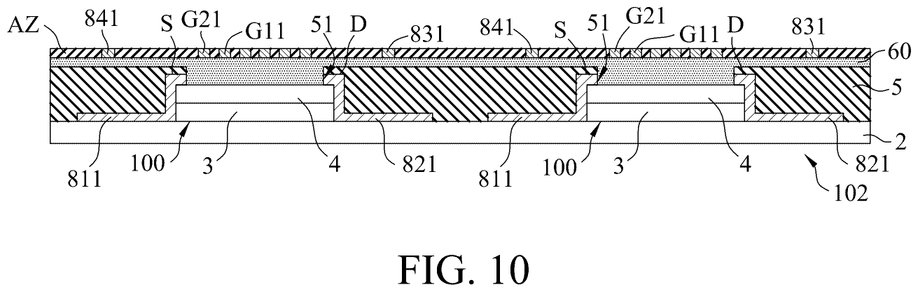

After that, in step (g), a positive photoresist layer (AZ) is formed on a surface of the second semi-finished product 102 (i.e., a surface of the polymer electrolyte film 60), followed by removing portions of the positive photoresist layer (AZ) at locations where the first gate electrode connection wires 831, the second gate electrode connection wires 841, the first gate electrode connection pad 832, and the second gate electrode connection pad 842 are to be formed subsequently, and at locations where the first gate electrodes (G11) and the second gate electrode (G21) are to be formed later, so as to form AZ openings (V) from which the polymer electrolyte film 60 is exposed, thereby obtaining a first structure as shown in FIG. 9. Next, in step (h), gold (having a thickness of 80 nm) and titanium (having a thickness of 5 nm) are deposited sequentially at sites where the portions of the positive photoresist layer (AZ) are removed (i.e., deposited sequentially on the surface of the polymer electrolyte film 60 that is exposed from the AZ openings (V)), so as to form the first gate electrode connection wires 831, the second gate electrode connection wires 841, the first gate electrode connection pad 832, the second gate electrode connection pad 842, the first gate electrodes (G11), and the second gate electrode (G21), thereby obtaining a second structure as shown in FIG. 10. Finally, the remaining of the positive photoresist layer (AZ) and portions of the polymer electrolyte film 60 underneath the remaining of the positive photoresist layer (AZ) (i.e., portions of the polymer electrolyte film 60 where none of the first gate electrode connection wires 831, the second gate electrode connection wires 841, the first gate electrode connection pad 832, the second gate electrode connection pad 842, the first gate electrodes (G11), and the second gate electrode (G21) are formed thereon) are removed, so as to obtain the polymer electrolyte layer 6 that is patterned, thereby obtaining the graphene optical device as shown in FIG. 1.

By substituting the gate dielectric material conventionally used with the polymer electrolyte, the graphene optical device according to the disclosure attains the gate doping effect at the gate bias voltage of merely about 1, which effectively reduces the operating voltage of the graphene optical device. In addition, because the polymer electrolyte film 60 includes the photoresist, processes for making the polymer electrolyte layer 6 that is patterned can be performed using photolithography, thus simplifying the patterning process. Moreover, with the design of the array arrangement of the graphene transistors (T) (the array of the GFETs) on the base 2, the disadvantage of an overly large surface area of a traditional transistor can be solved by reducing the surface area of each of the graphene transistors (T), and the total luminous intensity of the graphene optical device can be improved by increasing the number of graphene transistors (T) per unit surface area of the graphene optical device.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A graphene optical device, comprising:
a base;
a plurality of graphene transistors arranged on said base, each of said plurality of graphene transistors including a graphene layer formed on said base, a metal nanoparticle layer disposed on said graphene layer, an insulation layer, a polymer electrolyte layer, and an electrode unit, said electrode unit including a source electrode and a drain electrode disposed at two opposite sides of said metal nanoparticle layer, and a first gate electrode component and a second gate electrode component disposed in a position between said source electrode and said drain electrode, said insulation layer covering said source electrode and said drain electrode, and having an opening from which said metal nanoparticle layer is exposed, said first gate electrode component and said second gate electrode component being disposed correspondingly in position to said opening, said first gate electrode component including a plurality of first gate electrodes spaced apart at intervals, said second gate electrode component including a plurality of second gate electrodes spaced apart at intervals, said polymer electrolyte layer being disposed between said metal nanoparticle layer exposed from said opening and said plurality of first gate electrodes, and between said metal nanoparticle layer exposed from said opening and said plurality of second gate electrodes; and
an electrical connection structure electrically connected to said plurality of graphene transistors, and including a source electrode connecting unit which is electrically connected to said source electrodes of said electrode units of said plurality of graphene transistors, a drain electrode connecting unit which is electrically connected to said drain electrodes of said electrode units, a first gate electrode connecting unit which is electrically connected to said plurality of first gate electrodes of said first gate electrode components of said electrode units, and a second gate electrode connecting unit which is electrically connected to said plurality of second gate electrodes of said second gate electrode components of said electrode units.

2. The graphene optical device as claimed in claim 1, wherein said plurality of graphene transistors are arranged in rows and columns, and in each of said columns, said source electrodes of said electrode units of said plurality of graphene transistors are located at a first side of said each of said columns, and said drain electrodes of said electrode units are located at a second side of said each of said columns opposite to said first side.

3. The graphene optical device as claimed in claim 1, wherein said source electrode connecting unit includes a plurality of source electrode connection wires which connect said source electrodes in parallel, and a source electrode connection pad which is electrically connected to said plurality of source electrode connection wires.

4. The graphene optical device as claimed in claim 3, wherein said drain electrode connecting unit includes a plurality of drain electrode connection wires which connect said drain electrodes in parallel, and a drain electrode connection pad which is electrically connected to said plurality of drain electrode connection wires.

5. The graphene optical device as claimed in claim 4, wherein said first gate electrode connecting unit and said second gate electrode connecting unit are disposed on said insulation layer and electrically isolated from said source electrode connecting unit and said drain electrode connecting unit by said insulation layer.

6. The graphene optical device as claimed in claim 5, wherein said first gate electrode connecting unit includes a plurality of first gate electrode connection wires which connect said plurality of first gate electrodes in parallel, and a first gate electrode connection pad which is electrically connected to said plurality of first gate electrode connection wires.

7. The graphene optical device as claimed in claim 6, wherein said second gate electrode connecting unit includes a plurality of second gate electrode connection wires which connect said plurality of second gate electrodes in parallel, and a second gate electrode connection pad which is electrically connected to said plurality of second gate electrode connection wires.

8. The graphene optical device as claimed in claim 1, wherein, in each of said plurality of graphene transistors, said plurality of first gate electrodes and said plurality of second gate electrodes extend toward each other and are alternately arranged in an interdigitated manner.

9. The graphene optical device as claimed in claim 8, wherein said plurality of first gate electrodes and said plurality of second gate electrodes are arranged at regular intervals ranging from 100 nm to 2 μm.

10. The graphene optical device as claimed in claim 9, wherein each of said plurality of first gate electrodes has a first width, each of said plurality of second gate electrodes has a second width, and each of said regular intervals has a third width, each of said first width, said second width and said third width ranging from 100 nm to 2 μm, said first width, said second width and said third width being equal.

11. The graphene optical device as claimed in claim 1, wherein said base is made of a polymer material and has flexibility.

12. The graphene optical device as claimed in claim 1, wherein said metal nanoparticle layer includes a plurality of metal nanoparticles, said plurality of metal nanoparticles being made of a precious metal.

13. The graphene optical device as claimed in claim 12, wherein the precious metal is selected from the group consisting of gold (Au), platinum (Pt), silver (Ag), and combinations thereof.

14. The graphene optical device as claimed in claim 1, wherein said insulation layer is made of an insulation material selected from the group consisting of a polymer, an inorganic oxide, and a nitride.

15. The graphene optical device as claimed in claim 1, wherein said polymer electrolyte layer includes a polymer electrolyte and a photoresist, and has developing ability.

16. The graphene optical device as claimed in claim 15, wherein said polymer electrolyte is a solid electrolyte material.

17. The graphene optical device as claimed in claim 16, wherein the solid electrolyte material is selected from the group consisting of a mixture of polyethylene oxide (PEO) and lithium bis(trifluoromethanesulfonyl)imide (Li[(CF₃SO₂)₂N]; LiTFSI), and a mixture of carboxylated cellulose microfibrils (CCMFs) and carboxylated cellulose nanofibrils (CCNFs).

18. The graphene optical device as claimed in claim 15, wherein a weight ratio of said polymer electrolyte to said photoresist ranges from 1:2 to 2:1.

19. The graphene optical device as claimed in claim 18, wherein the weight ratio of said polymer electrolyte to said photoresist ranges from 7:10 to 1:1.

20. The graphene optical device as claimed in claim 15, wherein said photoresist is a positive photoresist or a negative photoresist.
